(19) United States
(12) Patent Application Publication
(10) Pub. No.: US 2006/0096706 A1
(43) Pub. Date: May 11, 2006

(54) Dry etching apparatus and a method of manufacturing a semiconductor device

(75) Inventors: Naoyuki Kofuji, Niiza-shi (JP); Masahito Mori, Tokyo (JP); Ken'etsu Yokogawa, Tsurugashima-shi (JP); Naoshi Itabashi, Tokyo (JP); Kazunori Tsujimoto, Tokyo (JP); Shin'ichi Tachi, Sayama-shi (JP)

Correspondence Address: MATTINGLY, STANGER, MALUR & BRUNDIDGE, P.C., 1800 DIAGONAL ROAD, SUITE 370, ALEXANDRIA, VA, 22314, US

(73) Assignee: HITACHI, LTD.

(21) Appl. No.: 11/315,316

(22) Filed: Dec. 23, 2005

Related U.S. Application Data
(63) Continuation of application No. 09/363,191, filed on Jul. 29, 1999.

(30) Foreign Application Priority Data
Jan. 19, 1999 (JP) 11-010172

(51) Int. Cl. H01L 21/306; C23F 1/00

(52) U.S. Cl. 156/345.34; 156/345.33

(57) ABSTRACT

The processing with a low gate rate of destruction and high anisotropy is achieved in dry etching. Plasma is generated by ECR resonance of electromagnetic wave which arose by supplying Ultra High Frequency electric power in microstripline 4 arranged on the atmosphere side of a dielectric 2, which separates a vacuum inside and an outside and magnetic field. A conducting layer is etched by this plasma, which is stable and uniform plasma.

### BACKGROUND OF THE INVENTION

1. Field of the Invention

This invention concerns the production technique of a semiconductor device, including dry etching processes of the wiring of the semiconductor device using effective magnetic field plasma generator for the dry etching process and this magnetic field plasma generator.

2. Description of the Related Art

Until now, an effective magnetic field plasma generator has been used for the process of the plasma treatment used in the manufacturing of a semiconductor device. For example, this effective magnetic field plasma generator has been described in Laid Open No. 8-337887 and Laid Open No. 9-321031.

Laid Open No. 8-337887 disclosed, as shown in FIG. 2, the microstrip antenna (MSA) comprising a discoidal electrode 1 which was grounded, dielectric 2, and a high frequency discoidal electrodes 3 installed to face discoidal electrode 1 through a dielectric. The plasma of the reactive gas was formed by electron cyclotron resonance (ECR) between the electromagnetic wave which the MSA radiates when a microwave was supplied to high frequency electrode 3 and the magnetic field formed by a solenoidal coil in the vacuum chamber. The sample was processed by irradiating the sample, retained on the support with this plasma. The reactive gas was supplied from the dielectric shower plate which faced the sample. The MSA was arranged in the dielectric atmosphere side which separates the inside in the vacuum chamber from the outside.

Laid Open No. 9-321031 disclosed that the plasma was formed by ECR resonance of an electromagnetic wave which the MSA radiates by supplying the MSA in the vacuum chamber with a UHF wave and magnetic field formed by a solenoidal coil.

### SUMMARY OF THE INVENTION

In the recent processing of the semiconductor device, the processing in low pressure of 0.5 Pa or less is indispensable for anisotropic etching. In case that gate wiring or metal wiring which is electrically connected for gate wiring is etched, it becomes important that (1) the ion current density on the wafer is reduced (2) the in-plane distribution of the ion current density is equalized

However, in conventional effective magnetic field plasma generator, in condition of the low pressure, it was difficult to make the discharge of low ion current density and stably uniformity. Said Laid Open No. 8-337887, since the microwave is used, the wavelength is short for the chamber, in the chamber, the plasma of multiple modes can exist. Therefore, in the condition of the low-pressure low ion current, it was frequently dislocated between the modes in which the plasma existed, and it was proven that the discharge is not stabilized. And, said Laid Open No. 9-321031, since the MSA has been installed inside the vacuum chamber, the high-density plasma was generated in the vicinity in the antenna edge by the intense electric field in the edge of the MSA by near field of discoidal electrode 3, and it was proven that the uniform plasma could not be generated in the low-pressure region.

And the in-plane etching rate becomes unequal, the in-plane distribution of ion current density becomes unequal, and it influences the yield in consequence.

The purpose of this invention is to offer effective magnetic field plasma generator which uniforms the in-plane distribution of ion current density and etching rate, and stable and uniform discharge at low ion current density, in a low-pressure condition, and the method of manufacturing semiconductor device using the plasma generator. U.S. Pat. No 5,891,252 is incorporated herein by reference.

The purpose is achieved by as follows. (1) it is used that the plasma was formed by ECR resonance of electromagnetic wave which the antenna (MSA) radiates by supplying the MSA through the separation board outside the vacuum chamber with UHF wave of not less than 300 MHz and not more than 1 GHz and magnetic field formed by solenoidal coil. Since the UHF wave is used, the wavelength becomes substantially equivalent the chamber diameter, and only the plasma of the single mode can exist. Therefore, there is no instability of the plasma by the transposition between modes. And, by choosing the structure which installed the MSA in the atmosphere side of the dielectric (the separation board) which divides the vacuum chamber side and the atmosphere side of which the pressure is higher than in vacuum chamber, the generation of the high-density plasma by intense electric field in the discoidal electrode MSA edge by the near field is suppressed, and the uniform plasma can form even in the low voltage. Still, the Ultra High Frequency band means the frequency domain of not less than 300 MHz and not more than 1 GHz in this specification. And it is effective that the difference of CD gain of dense pattern and the sparse pattern decreases by making the distance between shower plate which supplies the gas and support under 100 mm. In addition, it becomes possible the difference in the CD gain is decreased by making the shower plate diameter under 3/4 of the wafer diameter.

(2) And, it is achieved by plasma treatment in the frequency of the Ultra High Frequency band, 0.1 Pa 0.5 Pa low-pressure condition, and at 0.6 mA/cm2 2 mA/cm2 low ion current density. Over 0.1 Pa pressure and over the 0.6 mA/cm2 ion current density, it is possible to maintain the practical etching rate. In the meantime, it is effective to make the ion current density not more than 2 mA/cm2 for the charge built-up reduction, and it is effective to make to be the pressure of 0.5 Pa or less in order to achieve anisotropic etching.

The discharge characteristic as the frequency applied under 0.5 Pa in the MSA changes is shown in FIG. 5. When the frequency is over 1 GHz, the low-density region of 2 mA/cm2 or less can not be realized in the low voltage of 0.5 Pa or less since there is a problem of the discharge instability. And, when the frequency is less than 300 MHz, since radiation efficiency of electromagnetic wave is bad, in this structure without plasma generation by near field electric field, the plasma discharge can not be maintained. That is to say, it is proven that in low-pressure of 0.5 Pa, and can efficiently generate the plasma of the low ion current density of 2 mA/cm2 or less is limited to the region of not less than 300 MHz and not more than 1 GHz.

(3) In addition, it is achieved by forming the magnetic field distribution which becomes the convex ECR plane in viewing from the antenna, doing the plasma treatment. Especially, it is effective that the intersection point between ECR plane and shower plate is arranged the antenna diameter inside. By doing like this, the ECR resonance is generated in the central part, and the plasma density of central part increases, and the uniform distribution can be formed.

Concretely, the small diameter coil is installed above the antenna. The inside diameter of this small diameter coil is smaller than the antenna diameter.

And, it may be controlled, when the plasma discharge is ignited it becomes the concave ECR plane in viewing from the antenna, and after the ignition it becomes the convex ECR plane. Because the ignitionability of the plasma discharge is bad in case of the convex ECR plane, and it is good in case of the concave ECR plane. Especially, the ignitionability is improved, when the intersection point between ECR plane and shower plate exists outside of the antenna diameter. It is possible to control the corrugated surface in such ECR plane by controlling the magnetic coil of the support periphery.

(4) In addition, when the plasma density becomes the outside high distribution, it is achieved that establishes the cavity division height not less than 30 mm in the antenna back surface. By doing like this, it is possible that it eases the concentration of the electric field in the circumference, and that it solves outside high distribution of the plasma density. Then, the in-plane distribution of the ion current density is equalized and would be able to achieve the in-plane equalizing of the etching rate.

(5) And, it is achieved by applying the feedback on the magnetic coil. Monitoring the change of plasma density under etching, in case that plasma density increased, make the curvature of the convex ECR increased in viewing from the antenna in case that plasma density decreased, make the curvature of the convex ECR increased in viewing from the antenna. Especially, when plasma density increases, the plasma density become the central high plasma distribution, on the other hand, when it decreases, it becomes the circumference high plasma distribution. Since when the multilayer is etched, the reaction product discharged in the plasma changes, according to a type of a etched film, the plasma density changes, it is effective especially to be monitored like this when the multilayer is etched.

### BRIEF DESCRIPTION OF THE DRAWINGS

FIG. 1 shows an example of dry etching apparatus of this invention.

FIG. 2 shows the microstrip antenna (MSA) structure.

FIG. 3 shows the electric field on discoidal electrode 3 of the TM01 mode MSA.

FIG. 4 shows the map of discharge stability of the apparatus of FIG. 1.

FIG. 5 shows Ultra High Frequency dependence of the ion current density.

FIG. 6 shows the distribution of radiation field intensity in the apparatus of FIG. 1.

FIG. 7 shows the direction of radiation electric field in the apparatus of FIG. 1.

FIG. 8 shows the example of line of magnetic force and the ECR plane in the apparatus of FIG. 1.

FIG. 9 shows the change of ion current density in-plane distribution by the magnetic field.

FIG. 10 shows the example of line of magnetic force in case of divergence magnetic field in the apparatus which has solenoidal coil 14.

FIG. 11 shows the relationship of uniformity between inside diameter of solenoidal coil and the ion current density in-plane distribution.

FIG. 12 shows the example of ECR plane in the apparatus of FIG. 10.

FIG. 13 shows the change of the in-plane distribution of the ion current density by magnetic field.

FIG. 14 shows the example of dry etching apparatus which established the cavity division in the earth conductor.

FIG. 15 shows the in-plane distribution of the ion current density of the apparatus of FIG. 14.

FIG. 16 shows the example of the apparatus with solenoidal coils 16.

FIG. 17 shows the relationship between curvature of the bottom convex magnetic field and uniformity of the in-plane distribution of the ion current density.

FIG. 18 shows the example of the feed back circuit for uniformly keeping ion current in-plane distribution under multilayer etching.

FIG. 19 shows the cross section structure of etched sample of the metal wiring.

FIG. 20 shows the cross section structure of the metal wiring after etching, resist ashing removal and wet processing.

FIG. 21 shows the relationship between distance between the sample and shower plate and sparse pattern CD gain.

FIG. 22 shows the situation of gate destruction in the metal wiring sample which etched by the apparatus of this invention.

FIG. 23 shows the flow of the CMOS gate manufacturing process.

### DETAILED DESCRIPTION OF THE INVENTION

### Embodiment 1

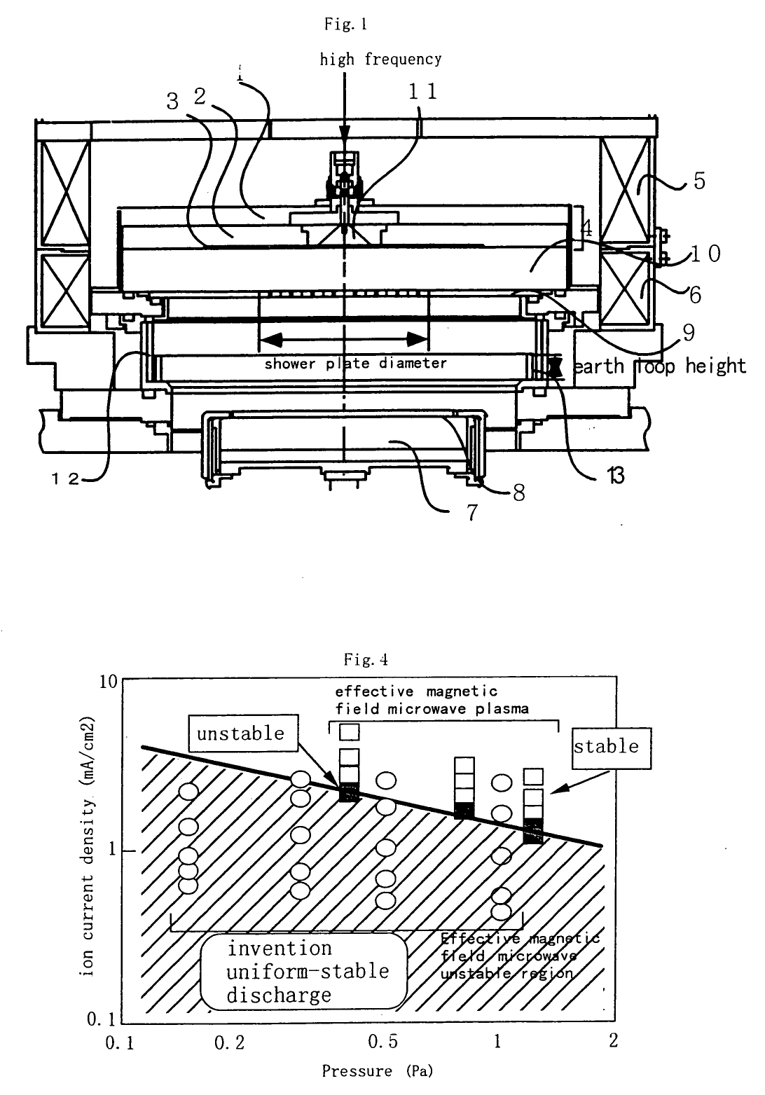

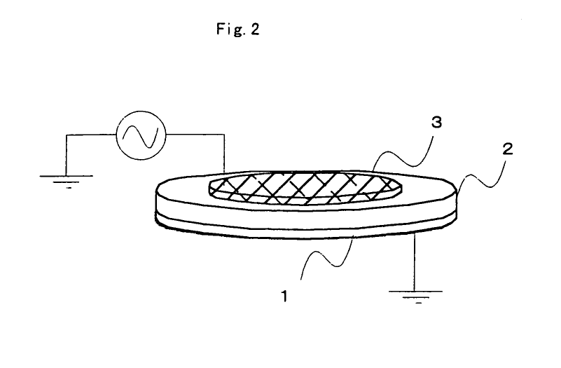

FIG. 1 is example of dry etching apparatus of this invention.

In this apparatus, the plasma of the reactive gas is formed in the vacuum chamber by the electron cyclotron resonance between electromagnetic wave which MSA4 radiates and magnetic field which is formed by solenoidal coil 5,6. Samples 8 is processed by irradiating this plasma in samples 8 retained on support 7. The supply of the uniform reactive gas is possible by supplying the reactive gas from shower plates 9 arranged for the plane which faced the sample. And, the generation of the high-density plasma on the edge of discoidal electrodes 3 by the near field is suppressed by installing MSA 4 in atmosphere side of dielectrics 10 which separates the inside in the vacuum chamber from the outside. And, the following can be also prevented: Change of characteristics by the corrosion of discoidal electrodes 3 and pollution of the sample by corrosion reaction product of discoidal electrodes 3. In this embodiment, quartz disk of the 35 mm thickness was used as dielectrics 10.

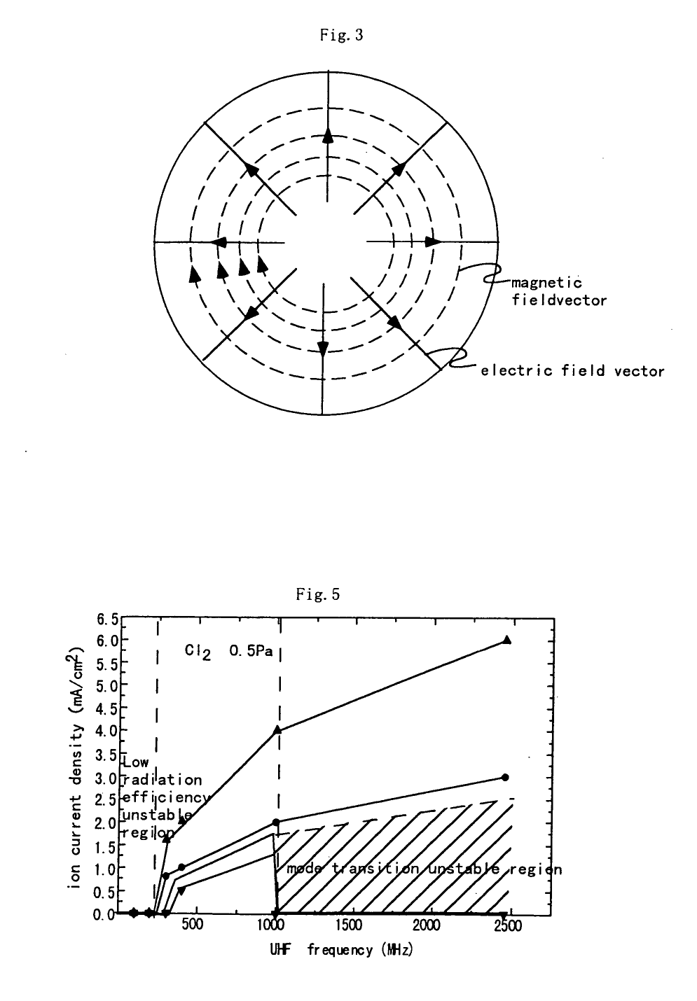

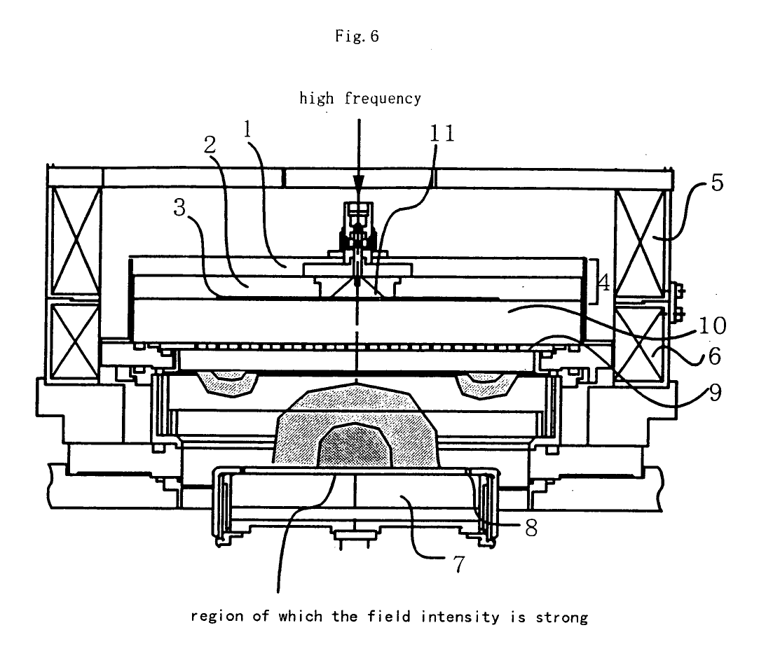

And, the stable plasma can be formed even in the low-pressure and low-density plasma by using high frequency of the Ultra High Frequency band as high frequency applied in discoidal electrode 3, in this apparatus. In addition, next two contrivance did in order to form the plasma of axisymmetry which was proper for the uniformity plasma formation. The one point is MSA4, in order that axisymmetric TM01 mode like FIG. 3 can resonate, frequency of the UHF wave which applies in discoidal electrode 3, diameter of discoidal electrodes 3, material of dielectric disk 2 and thickness are set. In this embodiment, the frequency of UHF wave was 450 MHz, diameter of discoidal electrodes 3 was 255 mm, and the alumina of the 20 mm thickness was used as dielectrics 2. The two-point is as follows: in order that the high frequency can be axisymmetrically supplied to the discoidal electrode 3, feed division 11 is made to be the conical state, and it becomes the structure which supplies the antenna from the conic top with electricity. And inner cylinder 12 of the quartz are let in as a metal pollution countermeasure in this apparatus. In case that inner cylinders 12 of such dielectric-ness are let in, when the inner cylinder comes out a little is eccentric, there is a problem in which the plasma deviates from the axisymmetric. In order to solve this problem, it arranged the conducting tubuldischargeylinders 13 grounded in the earth potential, and make the length of the overlap part which defines it in FIG. 1 as an earth loop height of inner cylinders 12 and conducting tubuldischargeylinders 13 not less than 10 mm, so that it can be perfectly prevented.

The result of evaluating discharge characteristic of the chlorine gas plasma using this apparatus is shown in FIG. 4. And, the discharge characteristic of conventional effective magnetic field microwave plasma generator is also shown for the comparison in FIG. 4. As FIG. 4, in the conventional effective magnetic field microwave plasma, the discharge became the instability, as the ion current density was lower, and as the pressure is lower. However, like this invention, by applying the frequency of the Ultra High Frequency band in the MSA, the stable and uniform discharge would be possible even in the region of low-pressure low ion current which could not realize in conventional effective magnetic field microwave plasma generator.

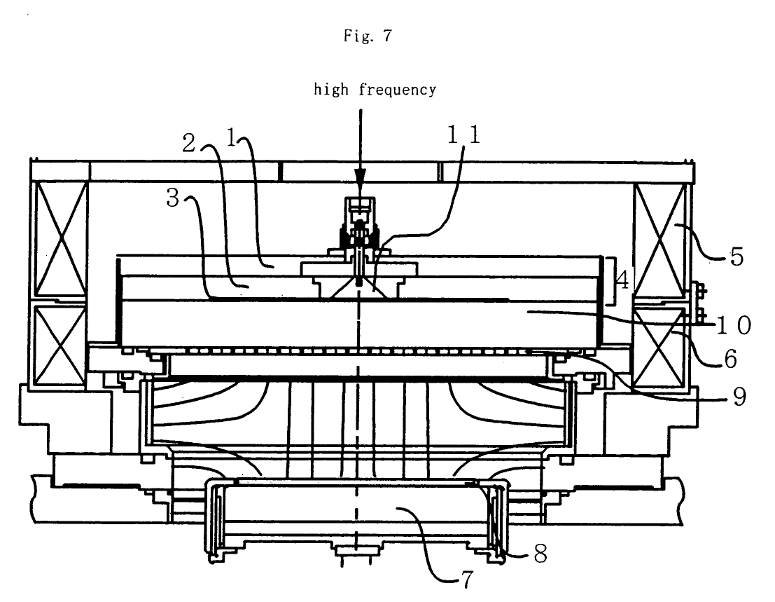

Still, plasma density in the center rises in the antenna structure of embodiment 1, since central field intensity is strong, as it is shown in FIG. 6, when there is no magnetic field or magnetic field are very weak. Therefore, in order to obtain more uniform plasma, it is important to increase plasma density of the circumference or decrease central plasma density. I explain the method for coordination of ECR magnetic field to increase plasma density of the circumference in embodiment 2, and the method to decrease central plasma density in embodiment 3 respectively.

### Embodiment 2

This embodiment describes formation method of ECR magnetic field where plasma density of the circumference increases, as it is above mentioned.

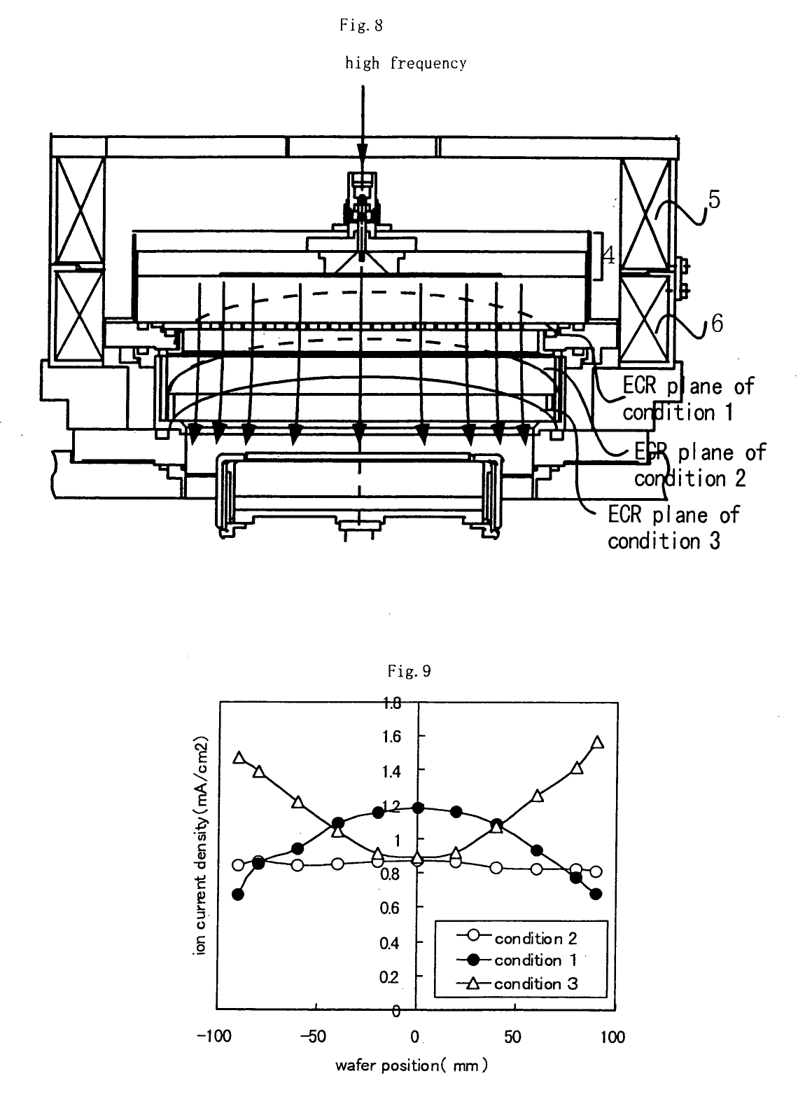

FIG. 7 shows the direction of the electric field in case of antenna structure of embodiment 1. In this structure, about the electric field, the length direction in the central part and the lateral in the periphery are generated. Therefore, like FIG. 8, when there is a magnetic field in length direction of the size which generates electron cyclotron resonance, since resistant resonance are generated in the circumference which orthogonalizes electric field and magnetic field, it is possible that the plasma density of the circumference increases. In order to make such magnetic field, like solenoidal coils 6 of FIG. 8, the solenoidal coil whose upper end plane is higher than discoidal conductors 3, whose lower end plane is lower than the shower plate lower end, which cover the circumference of shower plate from the antenna is needed. The distribution of the ion current density can be adjusted by adjusting the size of this current of solenoidal coils 6, and the size of the magnetic field in the length direction fluctuating.

For example, like condition of 1, in case that magnetic field strength is weak and a region (it is abbreviated to the following ECR plane) where causes the electron cyclotron resonance is outside of the vacuum treatment room, like FIG. 9, the ion current density distribution of the central high is formed. On the other hand, like conditions of 3, the magnetic field strength is strong and the ECR plane is inside of the vacuum treatment room perfectly, the circumference high distribution is formed. Especially, when the magnetic field strength is strong in the circumference, the ECR plane is located only in the circumference (conditions of 2), like FIG. 9, the high uniform plasma can be realized.

### Embodiment 3

In this embodiment, the method to decrease central plasma density as mentioned above.

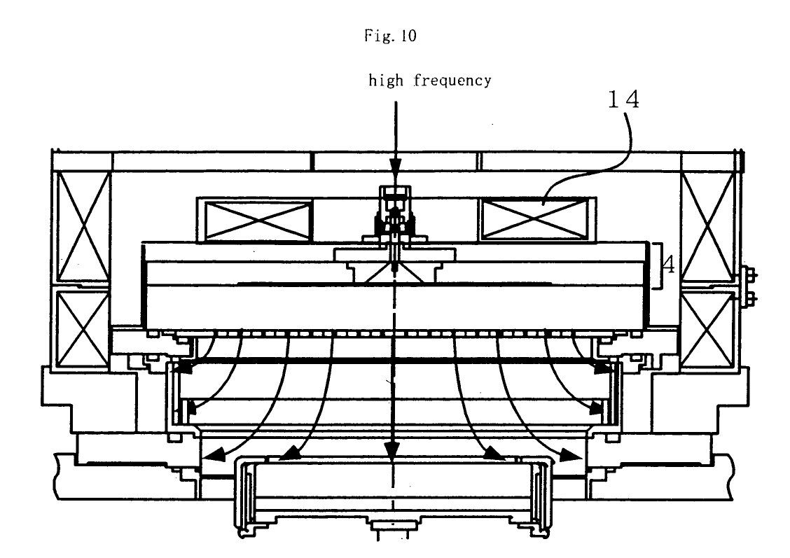

When divergence magnetic field like FIG. 10 was used, since it diffuses in the circumference direction as the plasma accords with magnetic field, the central plasma density can be reduced. It could be realized by installing solenoidal coil 14 whose inside diameter is small at MSA 4 upper part, in order to make such divergence magnetic field.

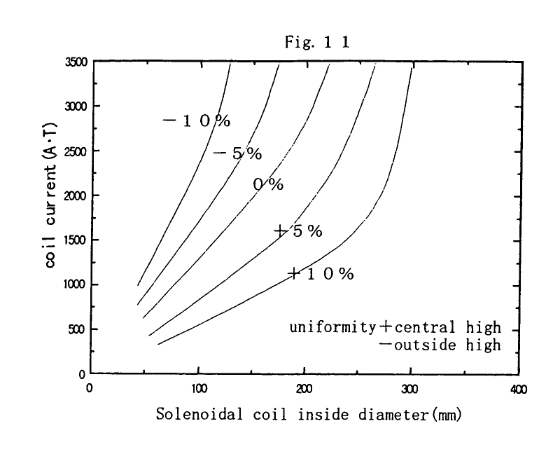

The relationship between inside diameter of solenoidal coil 14 and uniformity is shown in FIG. 11. Wafer in-plane distribution of the ion current density takes the positive value which shows the crown, when the inside diameter of solenoidal coil is bigger than the antenna diameter, even if the coil current is increased. From the point that inside diameter is less than 255 mm of antenna diameter, the uniformity would change, as it is dependent on the coil current. As the current is increased, it would be able to adjust from the positive uniformity which shows the crown distribution, uniformity 0% which show that the wafer in-plane distribution is uniform, and the negative uniformity which shows outside high distribution. From this fact, in order to make the uniform plasma, it is suitable that solenoidal coils 14 whose inside diameter is smaller than the antenna diameter are installed.

### Embodiment 4

In this embodiment, the relationship between convex shape of the ECR plane and ion current density is shown.

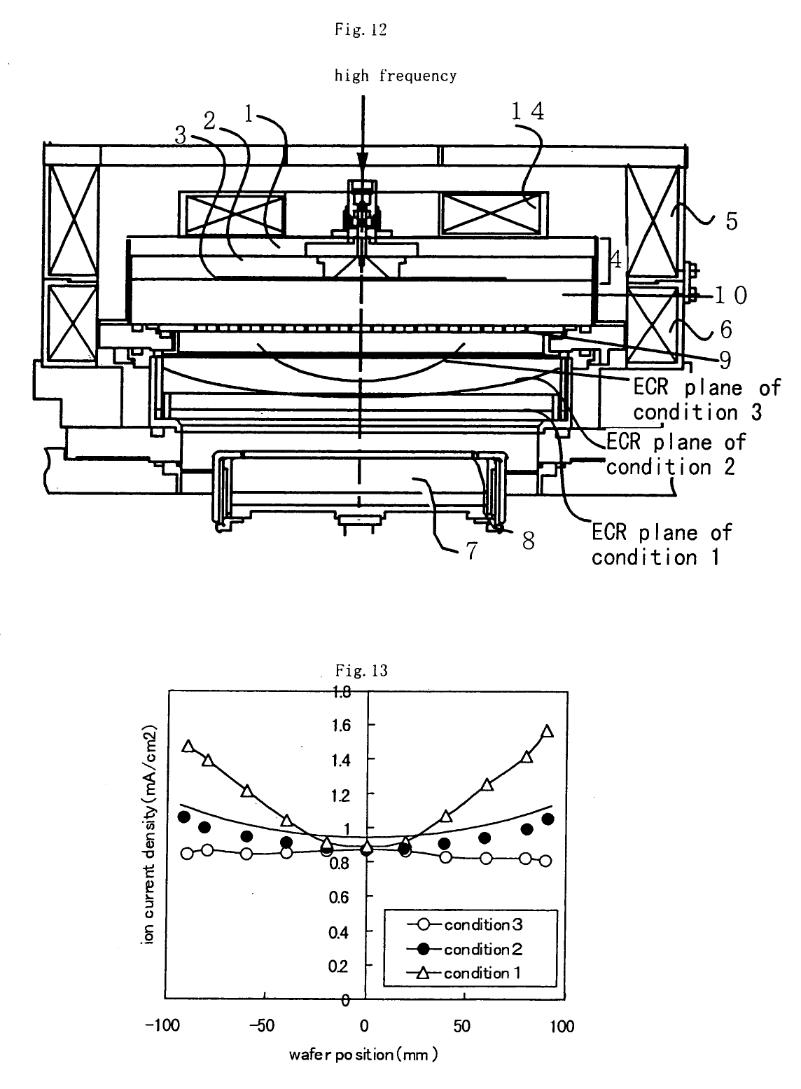

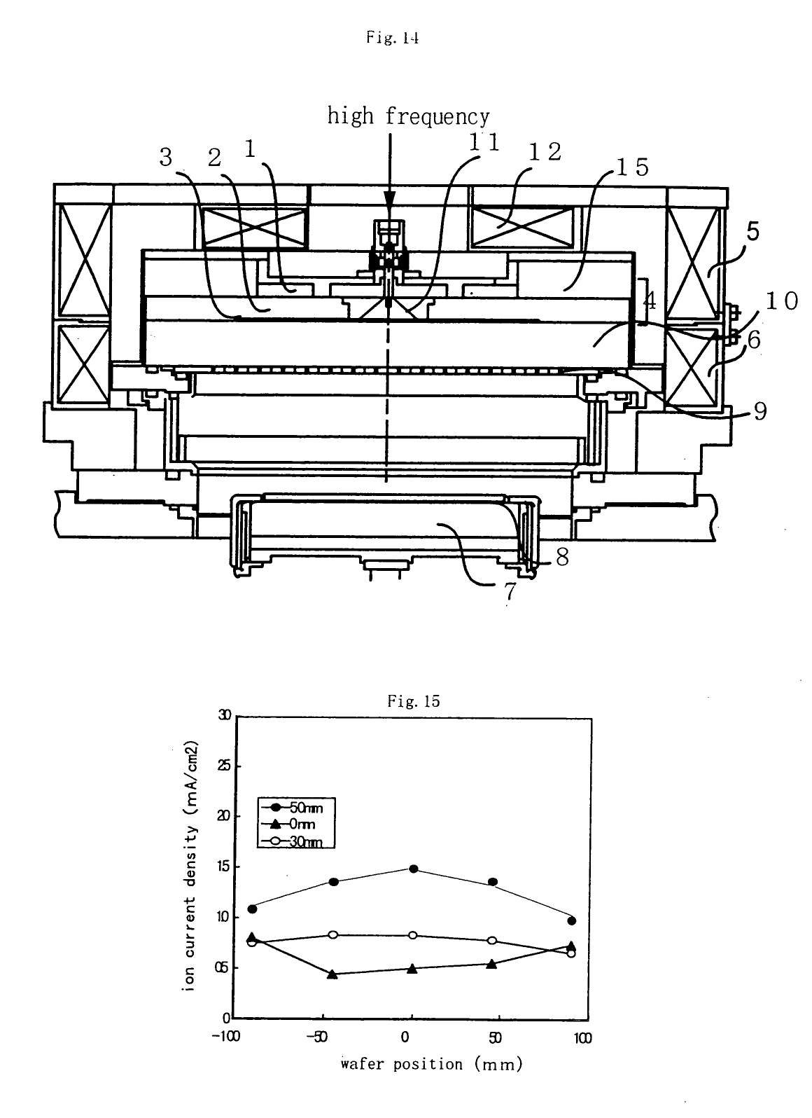

Using the solenoidal coils of embodiment 2 and 3, the equalizing of the in-plane distribution of ion current density was attempted. The in-plane distribution of the ion current density is shown in FIG. 13, adjusting the current of two solenoidal coil, as show in FIG. 12, on the condition of magnetic field in which the ECR plane is flat (condition of 1), magnetic field (conditions of 2) adjusted in order to become bottom convex, curvature besides are increased, magnetic field (conditions of 3) in which the ECR plane in the periphery comes out on the outside in the vacuum chamber. In the condition that the curvature of the ECR plane is big, when the ECR plane in the periphery does not come out outside in the vacuum chamber, the distribution of circumference high can only be got. Only under the condition that the periphery in the ECR plane came out outside in the vacuum chamber, it was proven that the distribution from uniformity to the crown is obtained.

Next, by convexing of the ECR plane in the top, the in-plane distribution of the ion current density was measured. It was confirmed that the in-plane distribution of the ion current density became uniform only under the condition central part ECR plane come out in outside this vacuum chamber also this apparatus composition, as well as embodiment 2.

### Embodiment 5

This embodiment shows the method for raising the in-plane uniformity with the lowering of ion current density distribution of the outside high.

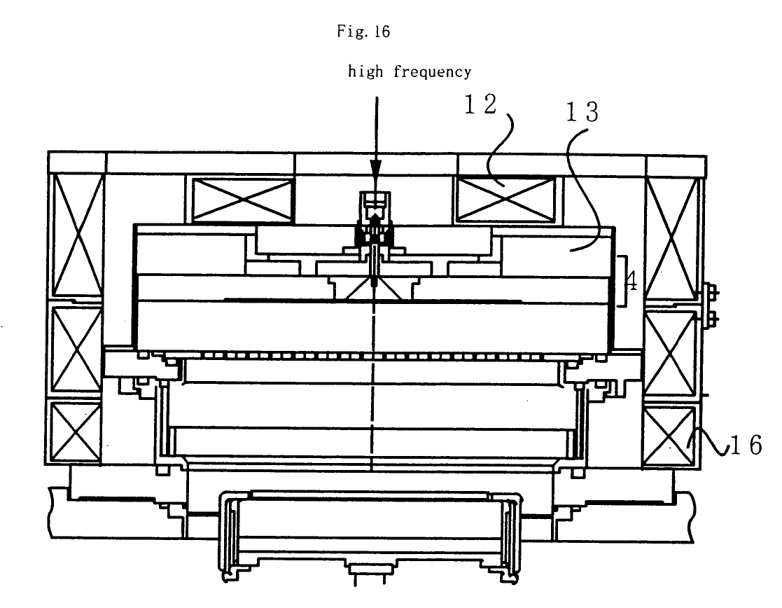

There is a method for equalizing ion current density, even in the top convex magnetic field of conditions 3 of embodiment 2. Like FIG. 14, cavities division 15 of the ring formation is established in discoidal electrode 1, so that the field intensity of the circumference of discoidal electrode 3 is reduced, and the ion current density of the circumference is lowered. The in-plane distribution of the ion current density on sample 8 at this time is shown in FIG. 15. When the size of the cavity made over 30 mm, the plasma density of the circumference lowered, the outside high distribution was eased. And, plasma density also increased at this time.

### Embodiment 6

In this embodiment shows the relationship between ignition of plasma discharge and ECR plane of plasma treatment.

There is a problem that the ignitionability of the plasma is bad, when bottom convex ECR magnetic field of embodiments 3 was used.

In order to solve the problem, we examine as follows, the magnetic field distribution where the top of the ECR plane becomes convex, that is to say, on the condition of the concave ECR plane in viewing from the antenna, the plasma ignites, after that adjusting method the magnetic field distribution in order to the in-plane distribution of the ion current density become uniform.

In order to increase the convex curvature in the top of the ECR plane, like solenoidal coil 16 of FIG. 16, establish the solenoidal coil whose inside diameter is larger than the chamber diameter at the bottom from the antenna plane, and run the high current. Using such coil, top convex ECR magnetic field was made, and the plasma ignites by the charge for 1 second of 1200 W Ultra High Frequency electric power. After that, by switching bottom convex ECR magnetic field, that is to say, magnetic field distribution which becomes the convex ECR plane in viewing from the antenna, the uniform plasma was generated. By this way, it was confirmed that good ignitionability and stable and uniform discharge were kept.

Still, as equalizing of the plasma by the magnetic field control and improvement of the plasma ignitionability in embodiment 26, it is effective not only etching of wiring materials such as the gate metal but also etching of oxide film, insulating film materials such as Low K film.

### Embodiment 7

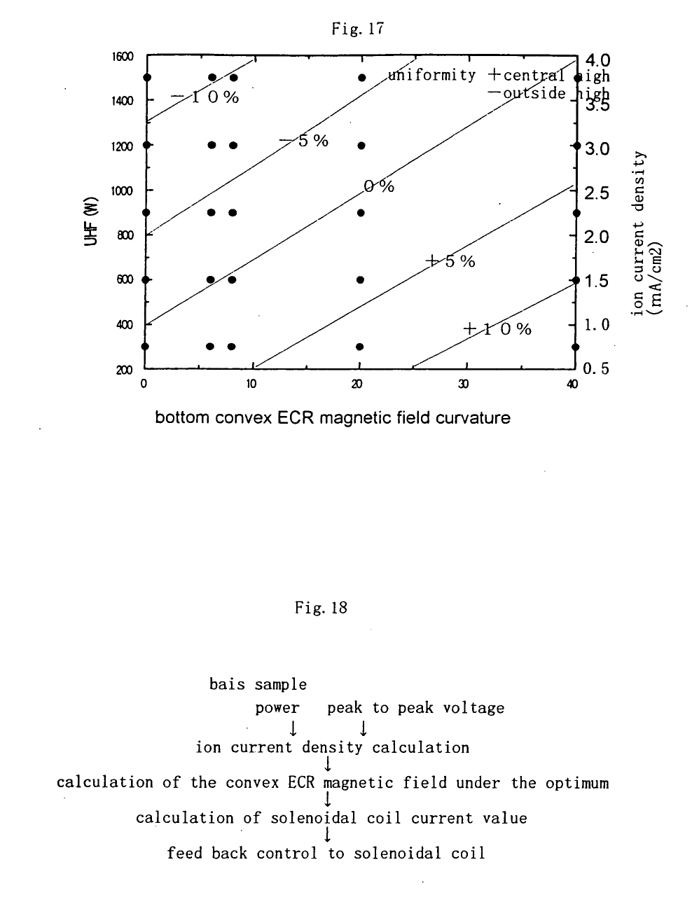

FIG. 17 shows the relationship curvature of ion current density measured in the apparatus of embodiment 3, the curvature of bottom convex ECR magnetic field, and in-plane uniformity of the ion current density. When the Ultra High Frequency electric power was heightened the ion current density is increased in same condition of the curvature of bottom convex ECR magnetic field, the uniformity of the ion current density in-plane distribution changes from positive in which shows the crown to negative which shows the circumference high.

From this fact, when the sample of the multi-layer film structure is etched, the ion current density changes, it is anticipated that the in-plane uniformity of the ion current density lowers, by the change of the type of etching reaction product discharged in the plasma since the etched material changes. Therefore, it is necessary to change the curvature of the bottom convex ECR magnetic field with the change of the ion current density in order to maintain the in-plane distribution of the uniform ion current density under etching of the sample of the multilayer structure.

In order to respond in this, like FIG. 18, the ion current density was calculated from the relationship between power of the bias applied to the sample and peak to peak voltage (difference in minimum value of bias voltage and maximum value of bias voltage), and using the result the optimum value of the curvature of bottom convex ECR magnetic field was calculated, and the system which feed back in the solenoidal coil current was developed. Using this system, it is possible to uniformly keep the ion current density in-plane distribution under etching of the sample of multilayer structure

### Embodiment 8

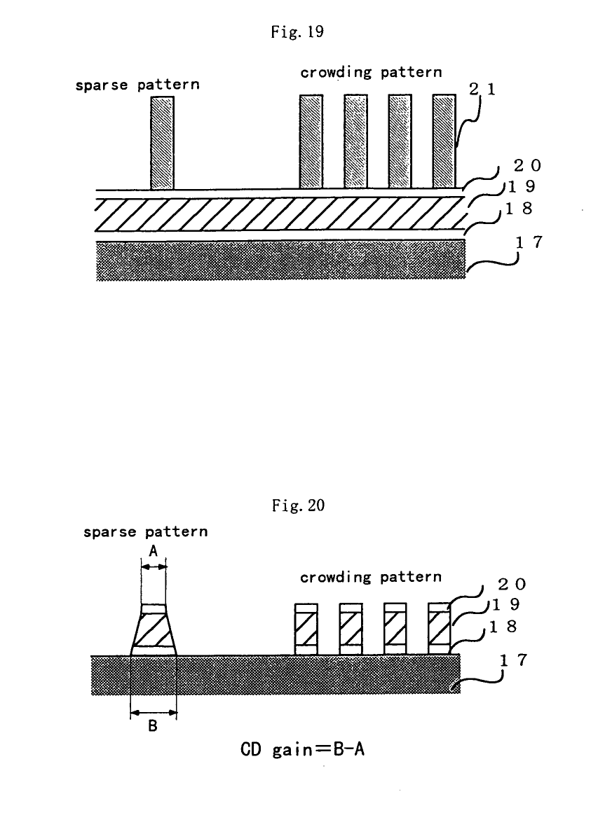

This embodiment shows the example of etching multilayer wiring. Metal wiring of the multilayer structure was etched, using the apparatus of embodiments of 7. As it is shown in FIG. 19, as a etched sample, following sample is used. The sample is produced by forming silicon oxide film 15 on the gate wiring by CVD, forming titanium nitride (TiN)18 on the silicon oxide film, forming aluminumcoppersilicon mixed crystal (Al—Cu—Si)19 on the titanium nitride film, forming titanium nitride (TiN)20 on the Al—Cu—Si film, forming resist mask 21 on the TiN 20 film. This sample was etched as following condition. It is using plasma of the mixed gas of C12 and BC13, CH4, 4% Ar dilution gas (it is abbreviated to the following NR), low-pressure of 0.5 Pa, Ultra High Frequency electric power 800 W which achieves low ion current density of 1 mA/cm2, and this sample was applied RF bias of 40 W 800 kHz. After etching, ashing the resist by mixed gas plasma of CF4 and O2, treating wet by NMD-3, the shape is shown in FIG. 20.

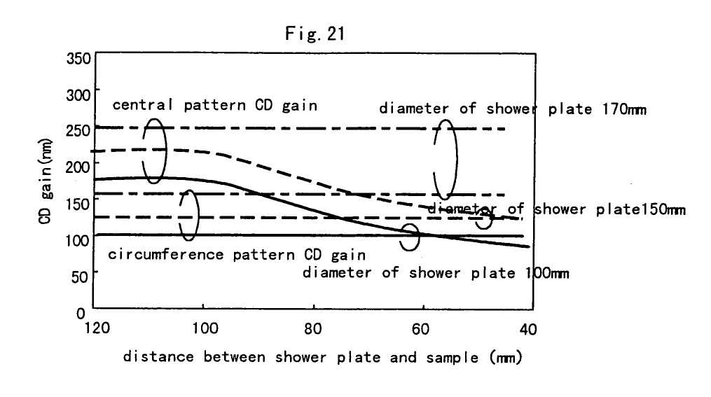

The relationship between CD gain of the sparse pattern shown in FIG. 20 and distance between samples-shower plate was measured. The result is shown in FIG. 21. Still, the CD gain calls etching pattern dimension fatness quantity (thin quantity), as shown in FIG. 20.

There was a problem in which CD gain of the central pattern increased in comparison with the pattern of the circumference in the etching condition of the prior apparatus whose distance between shower plate and support is not less than 100 mm. However, when the distance between shower plate and support is less than 100 mm, CD gain of the central pattern is reduced, the difference of CD gain between circumference pattern and the central pattern is decreasing. And the shower plate diameter shown in FIG. 1 was also an important factor to achieve this effect. There is no effect when the shower plate diameter is 170 mm. The effect of the CD gain reduction appears when shower plate diameter 150 mm or less in which the shower plate diameter becomes 3/4 of the wafer diameter. In shower plate diameter 100 mm, by shortening the distance between samples-shower plate at 60 mm, the processing could be carried out without the in-plane difference of the CD gain.

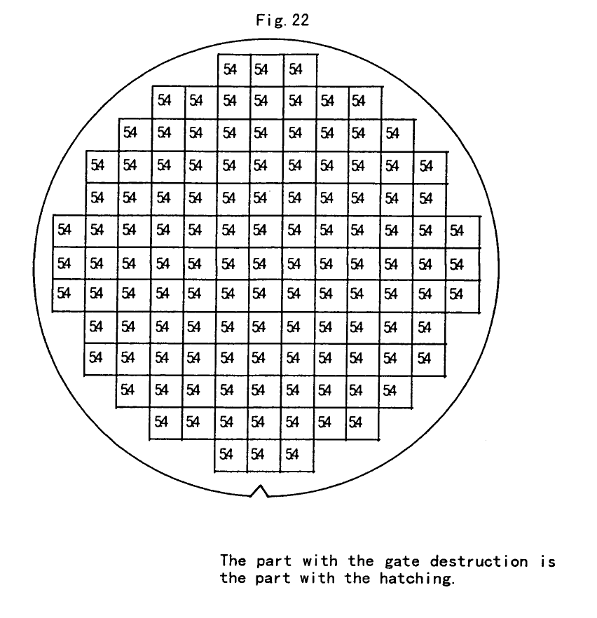

FIG. 22 shows the result of measuring the destruction of the gate of the sample which etched under the condition of shower plate diameter 100 mm and distance between sample-shower plates 60 mm. The black part which shows the IC chip received the gate destruction is not completely seen.

That is to say, by low ion current density of 1 mA/cm2 or less, even low pressure of 0.5 Pa or less in which the anisotropic processing could be carried out, the etching can be carried out without the gate destruction.

Here, though the etching of the metal was described, the effect of distance between a sample and shower plates in this embodiment, and the effect of the etching in the low-pressure low ion current are similar to the etching of the gate.

Still, said dense pattern means, for example DRAM, the wiring pattern in the memory mat part, said sparse pattern means the wiring pattern in the peripheral circuits part.

### Embodiment 9

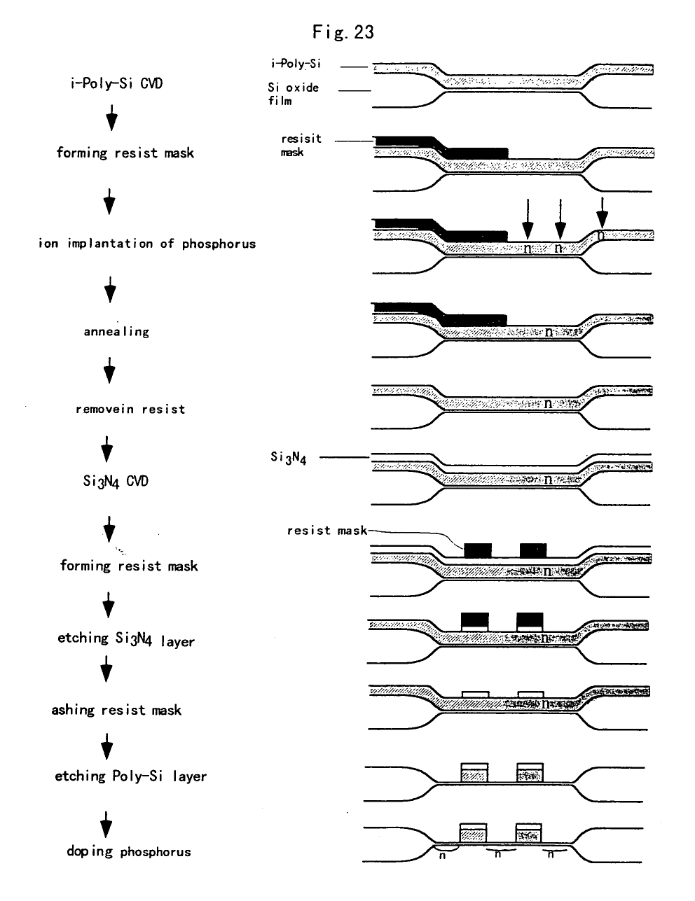

FIG. 23 shows the flow of the CMOS gate manufacturing process. To begin with, i-Poly is formed on silicone oxide film by the CVD method. The photoresist is coated on this i-Poly, the patterning is carried out by the lithographic technique and the resist pattern is formed. I-Poly layer next to n+Poly-Si layer is formed by the following steps. After P+ ion implantation is carried out using a resist pattern as a mask, removing a resist film, and annealing. Si3N4 is formed on i-Poly/n+Poly-Si layer by CVD. Next, the photoresist film is coated, patterned by lithographic technique, and forming resist pattern is formed. Si3N4 layer is etched anisotropy by CHF3/O2/Ar mixed gas plasma, using a resist pattern as mask. In addition, the Si3N4 mask is formed by removal of the resist in the ashing. Using the apparatus of embodiment 2, i-Poly/n+Poly-Si layer of this sample is etched anisotropy, using Si3N4 as a mask. Anisotropic etching was done as following condition. Using the mixed gas of C12, O2 and HBr, 0.10.2 Pa low pressure, 1 mA/cm2 low ion current density obtained by Ultra High Frequency electric power 800 W, applied RF bias of 800 kHz and 40 W to the sample. By etching by this apparatus, the etching was able to be carried out without the shape difference between i-Poly pattern and n+Poly-Si pattern. The phosphoric doping process was done using remained Si3N4/Poly-Si pattern as the mask, and the CMOS gate was formed.

### The Effect of the Invention

This invention performs the uniform etching without the gate destruction, so that plasma of a homogeneity of 1 mA/cm2 or less and low ion current density is realized even in the low pressure of 0.5 Pa or less of the anisotropic processing.

1-33. (canceled)

34. A shower plate body utilized for a dry etching apparatus including a vacuum chamber in which a plasma for the etching is generated by applying an electromagnetic wave to an introduced gas, a sample holder in the chamber designed to hold a wafer with a predetermined diameter, a discoidal antenna coupled to a power supply that supplies an electromagnetic wave, and a separation plate used as dielectric between the antenna and the inside of the chamber, comprising:
a shower plate portion arranged in said shower plate body to introduce the gas into the vacuum chamber,
wherein a diameter of the shower plate portion is not more than three fourth of a diameter of the wafer.

35. A shower plate body according to the claim 34,
wherein said shower plate body is set within 100 nm in a distance between the shower plate and the sample holder.

36. A shower plate body according to the claim 34,
wherein the diameter of said shower plate portion is not more than 150 nm.
